(19) United States
(12) Patent Application Publication
(10) Pub. No.: US 2012/0227806 A1
(43) Pub. Date: Sep. 13, 2012

(54) PHOTOCROSSLINKABLE ELECTROLYTE COMPOSITION AND DYE-SENSITIZED SOLAR CELL

(75) Inventor: Takeya Sakai, Nagoya-shi (JP)

(73) Assignee: HAYASHI ENGINEERING INC., Nagoya-shi, Aichi (JP)

(21) Appl. No.: 13/510,687

(22) PCT Filed: Nov. 17, 2010
(86) PCT No.: PCT/JP2010/070424

§ 371 Date: May 18, 2012

(30) Foreign Application Priority Data
Nov. 18, 2009 (JP) 2009-263105

(51) Int. Cl. H01G 9/035; H01L 31/0224

(52) U.S. Cl. 136/256; 252/62.2

(57) ABSTRACT

Provided are an electrolyte composition useful in gelling or solidifying the electrolyte of a dye-sensitized solar cell, an electrolyte formed from the electrolyte composition, and a dye-sensitized solar cell. The electrolyte composition comprises a redox pair, an ionic liquid, and a photocrosslinkable liquid crystal polymer having a functional group represented by the following chemical formula (1) to form the electrolyte. Moreover, the dye-sensitized solar cell 1 comprises a photoelectrode 10, a counter electrode 20, and the photocrosslinked electrolyte 30 sandwiched between these two sheets of electrodes. In the formula m is 0 or 1; n is 1 to 3; c is 0 or 1; X is none, O, CH₂, N═N, C═C, C≡C, COO, or OCO; R₁ and R₂ are each representing H, an alkyl group, an alkyloxy group, or a halogen.

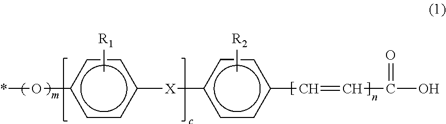

### CROSS REFERENCE TO THE RELATED APPLICATIONS

This application is based on and claims priority to Japanese application No. 2009-263105, filed Nov. 18, 2009, the entire disclosure of which is herein incorporated by reference as a part of this application.

### FIELD OF THE INVENTION

This invention relates to a photocrosslinkable electrolyte to be gelled or solidified and applicable for dye-sensitized solar cells, and relates to a photocrosslinkable electrolyte composition for forming the gelled or solidified electrolyte, and further relates to a dye-sensitized solar cell equipped with the above-mentioned electrolyte.

### BACKGROUND ART

Solar cells are semiconductor devices which transform sunlight energy into direct electricity energy. The crystal silicon type has been regarded as the first generation solar cells, the amorphous silicon type as the second generation solar cells, and the compound semiconductor type (GaAs etc.) as the third generation solar cells. Further, the dye-sensitized type is regarded as the fourth generation solar cell, and has attracted attention.

Generally a dye-sensitized solar cell is called as Gratzel cell or wet solar cell. For example, a cell of typical dye-sensitized solar cells comprises a photoelectrode, a counter electrode, such as platinum and carbon, being oppositely arranged to the photoelectrode, and an electrolyte sandwiched between these two sheets of electrodes. The photoelectrode comprises titanium dioxide powders baked on a transparent electrode so as to absorb pigments, such as ruthenium complex. The electrolyte comprises a redox couple of iodine (redox couple: I⁻/I₃⁻); and an organic solvent such as carbonate type solvent and nitrile type solvent as the solvent therefor.

According to such a dye-sensitized solar cell, the light incident on the cell first excites the pigments absorbed in the titanium dioxide, and then the excited pigments inject electrons into the titanium dioxide. As a result, the pigments serve as an oxidant to receive the electrons from a reductant (I⁻) in the electrolyte, and then the oxidant of pigments returns to a ground state. The reductant in the electrolyte turns into an oxidant (I₃⁻), and the oxidant in the electrolyte can receive an electron again on the counter electrode so as to return to a reductant (I⁻). In this way, by making electrons circulate through between both electrodes the photovoltaic power is generated in the dye-sensitized solar cell.

However, when such a liquefied electrolyte causes liquid leakage and solvent evaporation, cell performance will deteriorate. In order to improve the durability of the dye-sensitized solar cell, it is necessary to prevent the liquid leakage and solvent evaporation from the electrolyte. Therefore it is required for solar cells to have a complicated sealing structure to prevent such a problem. The sealing structure for preventing the liquid leakage and solvent evaporation of the electrolyte is, however, disadvantageous in production. From this point of view technical development for solidifying the electrolyte has been proceeded.

As a method for gelling an electrolyte, there has been mentioned physically-crosslinked type and chemically-crosslinked type gelations. The physically-crosslinked type gelatinizers, such as polyacrylonitrile or self-assembling gelatinizers, take advantage of the gelling nature under ordinary temperature atmosphere. They are liquefied at a high temperature to be injected into a cell and then gelatinized at an ordinary temperature. However, such a physically-crosslinked-type gel may cause liquid leakage at high temperatures because their flowability will become higher as temperature raises.

On the other hand, in the chemically-crosslinked type gelation, a monomer or oligomer having acrylic or methacrylic group and a radical polymerization initiator are added to an electrolytic solution to be dissolved therein and injected into a cell, followed by radical-polymerizing them in the cell. However, in the case of the electrolyte used for dye-sensitized solar cells, since iodine functions as a polymerization inhibitor, there is a problem that a crosslinking does not fully proceed.

For this reason, the method of introducing iodine, after gelling an electrolyte is proposed by W. Kubo, Y. Makimoto, T. Kitamura, Y. Wada, and S. Yanagida, Chem. Lett., 948 (2002), but this method makes the manufacturing method complicated, as well as makes diffusion rate of the iodine in the electrolyte slower resulting in inferior electromotive force.

[Non Patent Document 1] W. Kubo, Y. Makimoto, T. Kitamura, Y. Wada, and S. Yanagida, Chem. Lett., 948 (2002).

### DISCLOSURE OF THE INVENTION

### The Problems to be Solved by the Invention

Accordingly, in view of the problems of such conventional technology, an object of the present invention is to provide an electrolyte composition effective in gelling or solidifying an electrolyte of dye-sensitized solar cells.

Another object of the present invention is to provide a dye-sensitized solar cell comprising such an electrolyte composition.

### Means of Solving the Problems

As a result of intensive studies conducted by the inventors of the present invention in an attempt to solve the problem of the conventional technology, it has been found that (i) a polymer containing the functional group shown as the chemical formula (1) defined below can proceed photocrosslinking reaction even under existence of redox couples, such as iodine, that (ii) the gelled or solidified electrolyte by a photocrosslinking reaction can improve the durability of dye-sensitized solar cell by suppressing its flowability under high temperature atmosphere, and that (iii) such a dye-sensitized solar cell is also excellent in generating photovoltaic power, and thus he finally completed the invention.

That is, the present invention provides a photocrosslinkable electrolyte composition comprising a redox pair, an ionic liquid, and a photocrosslinkable liquid crystal polymer having a functional group represented by the following chemical formula (1):

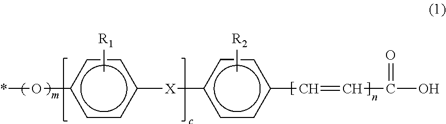

wherein, m is 0 or 1; n is 1 to 3; c is 0 or 1; X is none, O, CH₂, C═C, C≡C, COO, or OCO; R₁ and R₂ are each representing H, an alkyl group, an alkyloxy group, or a halogen.

For example, the above-mentioned redox pair may be a redox pair, such as iodine, and the above-mentioned ionic liquid may be a nitrogen-containing heterocyclic compound, an alicyclic amine, a fatty amine, or an aromatic amine.

Moreover, the present invention also includes a photocrosslinked electrolyte formed by light irradiation (for example, irradiation of ultraviolet of the wavelength of 380 nm or less) to the above-mentioned electrolyte composition.

Furthermore, the present invention also includes a dye-sensitized solar cell comprising a photoelectrode having an acceptance surface in one side, a counter electrode arranged on the opposing side of the acceptance surface of the photoelectrode, and the above-mentioned photocrosslinked electrolyte sandwiched between these two sheets of electrodes.

It should be noted that the present invention defines the term “electrolyte composition” as a material before enclosing to a battery cell, and the term “electrolyte” as a material after being enclosed to the battery cell.

### Effect of the Invention

According to the present invention, since the polymer having a specific functional group is contained in the electrolyte composition, even under existence of a redox pair, such as iodine, photocrosslinking reaction can be proceeded in the electrolyte composition by light irradiation.

The resulting gelled or solidified electrolyte can give the outstanding photovoltaic power to a solar cell while inhibiting electrolyte flow, and can improve the durability of a dye-sensitized solar cell even under high temperature atmosphere.

Furthermore, by irradiation of ultraviolet light to the electrolyte composition of the present invention, cell characteristics can be improved so as to enhance the photovoltaic current of the dye-sensitized solar cell.

### BRIEF DESCRIPTION OF THE DRAWINGS

In any event, the present invention will become more clearly understood from the following description of preferred embodiments thereof, when taken in conjunction with the accompanying drawings. However, the embodiments and the drawings are given only for the purpose of illustration and explanation, and are not to be taken as limiting the scope of the present invention in any way whatsoever, which scope is to be determined by the appended claims.

FIG. 1 is a sectional view showing the dye-sensitized solar cell containing the electrolyte composition of one embodiment of the present invention.

FIG. 2 is a figure showing the relationship between the photovoltaic-current value and the amount of ultraviolet which is irradiated from the back side of the counter electrode in Examples and Comparative Example of the present invention.

FIG. 3 is a view showing an image of the ultraviolet-irradiated electrolyte composition of one embodiment of the present invention obtained by observation using a polarization microscope under crossed-Nicol.

### DETAILED DESCRIPTION OF THE INVENTION

(Dye-Sensitized Solar Cell)

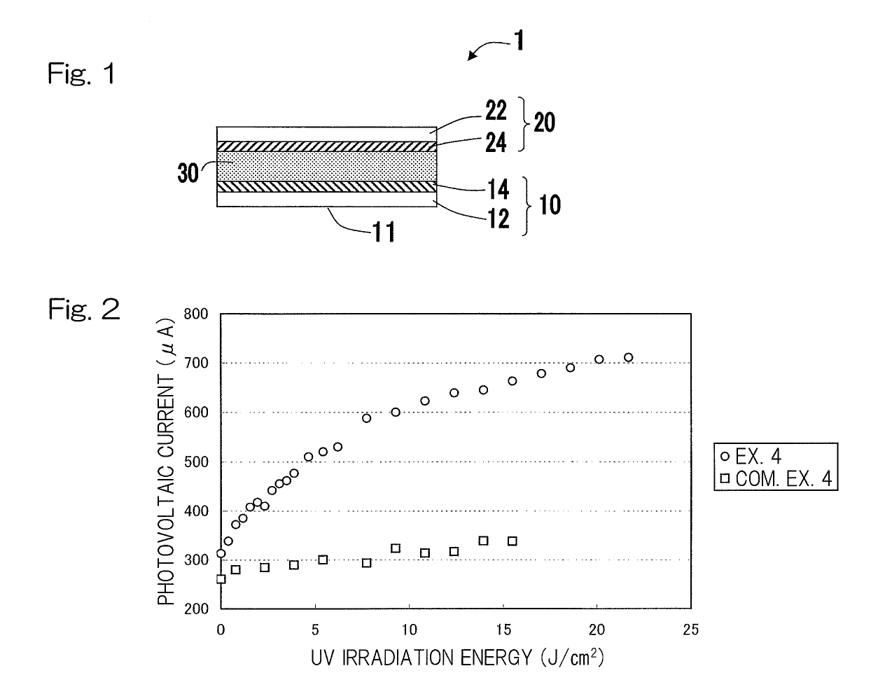

FIG. 1 is a sectional view showing one embodiment of the dye-sensitized solar cell comprising an electrolyte composition of this invention.

The dye-sensitized solar cell 1 schematically comprises a photoelectrode 10 having an acceptance surface 11, a counter electrode 20 arranged on the opposing side of the acceptance surface of the photoelectrode 10, and, an electrolyte 30 sandwiched with two sheets of these electrodes. The photoelectrode 10 comprises a transparent electrode 12 formed from glass, transparent polymer film, or the like, and a dye-absorbing layer 14 formed on the side of the electrolyte 30 (namely, the side opposing to the acceptance-surface 11) of the transparent electrode 12. The dye-absorbing layer comprises a sensitizing dye, such as ruthenium complex, absorbed physically or chemically by a porous object of the metal oxide (for example, TiO₂) being capable of supporting the sensitizing dye. On the other hand, the counter electrode 20 comprises a transparent electrode 22 and an electric conduction layer 24 formed on the side of the electrolyte 30 of the transparent electrode 22.

(Photocrosslinkable Electrolyte Composition)

The electrolyte composition of the present invention comprises a redox pair, an ionic liquid, and a photocrosslinkable liquid crystal polymer having a functional group shown by the following chemical formula (1).

(Redox Pair)

The redox pair can be suitably selected from what is generally used in electrolyte layers. Specifically, a redox pair of iodine and a redox pair of bromine are preferably used. As the redox pair of iodine, there may be mentioned the combination of iodine and various iodides (for example, lithium iodide, sodium iodide, potassium iodide, calcium iodide, TPAI (tetrapropylammonium iodide), etc.). Moreover, as the redox pair of bromine, there may be mentioned the combination of bromine and various bromides (for example, lithium bromide, sodium bromide, potassium bromide, calcium bromide, etc.). These redox pairs can be used singly or in combination of two or more.

(Ionic Liquid)

As the ionic liquid (ordinary temperature fused salt), there may be mentioned nitrogen-containing heterocyclic compounds, alicyclic amines, fatty amines, and aromatic amines. These ionic liquids can be used singly or in combination of two or more.

Among them, ionic liquids of imidazolium type, pyridium type, alicyclic amine type, and fatty amine type can be suitably used. Preferable one may include imidazolium type [e.g., 1-C₁₋₂₀-alkyl-3-methyl imidazolium, 1-C₁₋₂₀-alkyl-2,3-dimethyl imidazolium, imidazolium iodide compounds (e.g., 1,2-dimethyl-3-n-propyl imidazolium iodide, 1-methyl-3-n-propyl imidazolium iodide, 1-propyl-3-methyl imidazolium iodide, 1-butyl-3-methyl imidazolium iodide, 1-butyl-2,3-dimethyl imidazolium iodide, 1-hexyl-3-methyl imidazolium iodide, etc.). In particular, from the viewpoint of being applicable as a redox pair, imidazolium iodide compounds are more preferable.

(Photocrosslinkable Liquid Crystal Polymer)

The photocrosslinkable liquid crystal polymer used in the present invention has the functional group represented as the following chemical formula (1).

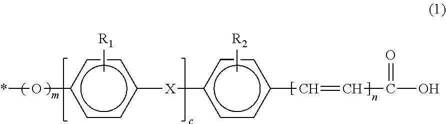

wherein, m is 0 or 1; n is 1 to 3; c is 0 or 1; X is none, O, CH₂, N═N, C═C, C≡C, COO, or OCO; R₁ and R₂ are each independently representing H, an alkyl group, an alkyloxy group, or a halogen (e.g., chlorine, fluorine, bromine, etc.).

The alkyl group in R₁ and R₂ may be any of linear chain and branched chain. The number of carbon atoms is usually about 1 to 10. Specifically, there may be mentioned methyl group, ethyl group, propyl group, i-propyl group, butyl group, i-butyl group, t-butyl group, pentyl group, hexyl group, heptyl group, octyl group, 2-ethylhexyl group, nonyl group, decyl group, and others. Among them, preferable one includes C₁₋₄ alkyl groups, such as methyl group and ethyl group.

The alkyloxy group in R₁ and R₂ may be any of linear chain and branched chain. The number of carbon atoms is usually about 1 to 10. Specifically, there may be mentioned methoxy group, ethoxy group, propyloxy group, i-propyloxy group, butoxy group, i-butoxy group, t-butoxy group, pentyloxy group, hexyloxy group, cyclohexyloxy group, heptyloxy group, octyloxy group, 2-ethylhexyloxy group, nonyloxy group, decyloxy group, and others. Among them, preferable one includes C₁₋₄ alkyloxy groups, such as methoxy group and ethoxy group.

Among the functional groups represented by the formula (1), the functional group may be preferably in the condition that m is 1; n is 1 to 3; c is 0 or 1; X is none, O, CH₂, COO, or OCO; R₁ and R₂ are each independently representing H, a C₁₋₄alkyl group, or a C₁₋₄alkyloxy group; and more preferably in the condition that m is 1; n is 1 to 2; c is 0; R₂ is H, a C₁₋₄alkyl group, or a C₁₋₄alkyloxy group.

The photocrosslinkable liquid crystal polymer used in the present invention is a molecule having a carboxyl group at the side chain end, which generates a salt if added to the above-mentioned ionic liquid. Two carboxyl groups at side chain end of the two polymer molecules dimerize to create a hydrogen bond, and thereby this polymer forms rigid structure so as to have liquid crystal nature. The polymer also has a photocrosslinkable nature in which the photoreaction of two side chain ends proceeds by optical irradiation of suitable wavelength light (for example, ultraviolet irradiation of 380 nm or less) to form a cyclobutane bond.

The photocrosslinkable liquid crystal type polymer may show a liquid crystal phase at 80-250° C., and preferably at about 100-200° C. It should be noted that the liquid crystal phase can be confirmed by polarization microscope observation, differential scanning calorimetry, X-ray diffraction measurement, and the like. Moreover, the number average molecular weight of the photocrosslinkable liquid crystal polymer indicated as the molecular weight of polystyrene may be for example about 15,000 to 45,000 preferably about 20,000 to 40,000.

Such a photocrosslinkable liquid crystal polymer may be a homopolymer of identical monomers containing a side chain (namely, photosensitive group) represented as the chemical formula (1), or may be a copolymer of different monomers, each of the monomer containing a side chain represented as the chemical formula (1). Further, it is also possible to copolymerize a unit containing a side chain represented as the chemical formula (1) with a unit which does not contain a photosensitive group. Furthermore, as long as the photocrosslinkable liquid crystal polymer shows liquid crystallinity, it is also possible to copolymerize a unit containing a photosensitive group with a monomer which does not show liquid crystallinity.

Such a monomer has a polymerizable group for polymerization, and the polymerizable group may be an addition-polymerizable group or a condensation-polymerizable group. As an addition-polymerizable group, there may be mentioned unsaturated aliphatic hydrocarbon groups (vinyl group, allyl group, etc.), unsaturated aliphatic carboxylic groups (acryloyl group, methacryloyl group, etc.), and the like. These addition-polymerizable groups can be used singly or in combination of two or more. Polymerization of the addition-polymerizable group can be carried out by using a known or common polymerization initiator. Examples of polymerization initiator may include azo compounds (for example, azobisisobutyronitrile), peroxides (for example, benzoyl peroxide), and the like. Moreover, as a condensation-polymerizable group, there may be mentioned hydroxyl group (including silanol group), amino group, and the like. It should be noted that the silanol group is usually produced by hydrolyzing an organochlorosilane compound in many cases.

In the electrolyte composition the photocrosslinkable liquid crystal polymer amount Q (wt %) to be added is preferably within the range of 5 wt %<Q<95 wt % based on the total amount (100 wt %) of a redox couple, an ion liquid, and a photocrosslinkable liquid crystal polymer. The amount Q is more preferably 10 wt %≦Q≦75 wt %. When the amount Q to be added is too small, gelation or solidification of the electrolyte may not be fully carried out, resulting in liquid leakage. In contrast, the amount Q to be added is too much, diffusion of the redox couple may be inhibited, resulting in lowering battery characteristics.

Moreover, the ratio of the photocrosslinkable liquid crystal polymer and the ionic liquid may be as weight ratio the (former)/(latter)=about 7/93 to 90/10, and may be preferably about 10/90 to 85/15.

In addition, the electrolyte composition of the present invention may contain various additives (a dispersant, a leveling agent, a plasticizer, a defoaming agent, etc.) if needed.

(Photocrosslinked Electrolyte)

When producing a dye-sensitized solar cell with the electrolyte composition of the present invention, various methods can be used as long as the electrolyte formed from the electrolyte composition is sandwiched with photoelectrode and counter electrode sheets. For example, (i) the cell may be produced by dissolving the above-mentioned electrolyte composition in an organic solvent or melting the above-mentioned electrolyte composition with heat to give an electrolyte composition liquid, and applying the liquid to a photoelectrode and/or a counter electrode to combine these two electrodes. Alternatively, (ii) the cell may be produced by inserting the above-mentioned electrolyte composition liquid into the gap of two opposed electrodes.

In either cases of (i) or (ii), the electrolyte composition can be gelled or solidified within two electrodes so as to effectively prevent evaporation of the solvent or liquid leakage of the electrolyte even without a sealing means.

That is, since the polymer containing a functional group represented as the chemical formula (1) has liquid crystallinity as well as photocrosslinkable property, the electrolyte of the present invention containing such polymer can be photocrosslinked by optical irradiation to a solar cell so as to make the solar cell possible to have an improved durability as well as excellent cell performance.

Moreover, if needed, ultraviolet radiation may be irradiated to the electrolyte sandwiched with a photoelectrode and a counter electrode so as to make the electrolyte further stiffened. As shown in the below-mentioned Examples, it was confirmed that the ultraviolet-irradiated electrolyte had some parts of light penetration when observed by a polarization microscope under crossed-Nicol as well as that such an ultraviolet-irradiated electrolyte improved cell characteristics.

Such a light penetration is thought to be caused by formation of small domains in the electrolyte indicating the phase-separated structure in the electrolyte. Reference 1 [Functional Material, vol. 24, No. 11, page 60, CMC publication (2004)] describes some examples in which solar cell characteristics are improved by the phase-separated structure. Therefore, in the same mechanism as the above examples, the electrolyte of the present invention is considered to have improved cell characteristics by the phase-separated structure.

### Examples

Hereinafter, the present invention will be demonstrated by way of some examples, which are not to be construed as limiting the scope of the present invention.

The method for synthesizing gelatinizers for electrolytes used in Examples of the present invention is shown below.

(Monomer 1)

Into 150 mL of ethanol (produced by NACALAI TESQUE, INC.) and 150 mL of water were added 100 g of trans-p-coumaric acid (produced by Tokyo Chemical Industry Co., Ltd.) and 130 g of 6-chloro-1-hexanol (produced by Tokyo Chemical Industry Co., Ltd.) and 100 g of potassium hydroxide, and the mixture were stirred under reflux conditions for 7 hours. The resultant was recrystallized by ethanol to obtain 4-(6-hydroxyhexyloxy) cinnamic acid. Then, into 40 mL of chloroform were added 10 g of the obtained product, 40 g of methacrylic acid, 0.8 g of sulfuric acid, and 0.2 g of hydroquinone to mix together, and the mixture were stirred under reflux conditions for 8 hours with removing water generated by dehydration reaction by using Dean-Stark tube. Thus obtained reaction liquid was concentrated with a rotary evaporator, followed by being poured into 2 L of water to obtain a precipitated solid. After filtering the precipitated solid, the solid was recrystallized with acetone to synthesize a monomer 1 shown in the following chemical formula (2).

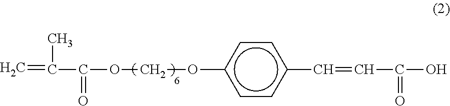

(Polymer 1)

The monomer 1 is dissolved in 1,4-dioxane at a concentration of 20 wt %, then AIBN (azobisisobutyronitrile) was added as a polymerization initiator at a concentration of 2 mol %, followed by leaving the mixture under atmosphere of 70° C. for 12 hours to carry out polymerization. The resultant polymerization solution was poured into 5 volumes of methanol to obtain a precipitated solid. The solid was filtered and dried to obtain a polymer 1 (the number average molecular weight indicated as styrene molecular weight: about 30,000). This polymer 1 presented liquid crystal phase within the range between 135 and 187° C.

The followings are Example of dye-sensitized solar cell produced by using electrolyte compositions of the present invention.

### Example 1

The photoelectrode was produced as follows. The titanium-oxide paste (produced by NISHINODA DENKO Co., Ltd.) was coated (coated area: 6 cm²) to a glass substrate (produced by NISHINODA DENKO Co., Ltd.) on which ITO (indium tin oxide) transparent electrode film was formed, and dried. Subsequently, the coated substrate was heat-treated with a hot plate heated at 400° C. to form titanium oxide film on the ITO electrode. The titanium-oxide-coated glass substrate was dipped in an aqueous solution of extracted hibiscus dye (produced by NISHINODA DENKO Co., Ltd.) for 12 hours to allow the surface of the titanium oxide film to carry the dye.

On the other hand, as a counter electrode was used a glass substrate comprising an ITO transference electrode (produced by NISHINODA DENKO Co., Ltd.) on the surface in which the ITO transference electrode was blacked out with pencil to form a carbon coating.

With the use of dimethyl sulfoxide (produced by NACALAI TESQUE, INC.) as a solvent, 3 wt % of the polymer 1, 17 wt % of 1-butyl-3-methylimidazolium iodide (produced by Tokyo Chemical Industry Co., Ltd., hereinafter referred to as i BM-IMD), 0.1 wt % of iodine (produced by Tokyo Chemical Industry Co., Ltd.), and 0.1 wt % of lithium iodide (produced by KISHIDA CHEMICAL Co., Ltd.) were added to produce an electrolyte. In the electrolyte, the weight ratio of the polymer 1 and BM-IMD is 15:85.

This solution was applied to both whole surface of the titanium oxide film carrying the dye formed on the ITO transparent electrode surface and whole surface of the carbon film of the counter electrode, then both substrates were placed on a hot plate at a temperature of 85° C. for 15 minutes to volatilize the dimethyl sulfoxide solvent. Subsequently, the temperature of the hot plate was elevated to 120° C. to warm both substrates sufficiently, then, the warmed substrates were pressed with contacting the carbon film surface with the titanium oxide film surface coated with the electrolyte composition solution. Then, these pressure-bonded substrates were left to be cooled to a room temperature to produce a cell. Although the cell did not equip with any special sealing mechanism for preventing solvent evaporation or liquid leakage, neither electrolytic liquid leakage nor evaporation of solvent arose in the obtained cell. It should be noted that evaporation of solvent was determined by visual observation, and the case where the amount of solvent between substrates is clearly decreased was evaluated as “evaporation of solvent”.

### Example 2

The photoelectrode and the counter electrode were produced in the same way as Example 1. With the use of dimethyl sulfoxide (produced by NACALAI TESQUE, INC.) as a solvent, 2 wt % of the polymer 1, 18 wt % of BM-IMD (produced by Tokyo Chemical Industry Co., Ltd.), 0.1 wt % of iodine (produced by Tokyo Chemical Industry Co., Ltd.), and 0.1 wt % of lithium iodide (produced by KISHIDA CHEMICAL Co., Ltd.) were added to produce an electrolyte. In the electrolyte, the weight ratio of the polymer 1 and BM-IMD is 10:90. With the use of this solution, was produced a cell in the same way as Example 1. Although the cell did not equip with any special sealing mechanism for preventing evaporation of solvent or liquid leakage, neither electrolytic liquid leakage nor evaporation of solvent arose in the obtained cell.

### Example 3

The photoelectrode and the counter electrode were produced in the same way as Example 1. With the use of dimethyl sulfoxide (produced by NACALAI TESQUE, INC.) as a solvent, 15 wt % of the polymer 1, 5 wt % of BM-IMD (produced by Tokyo Chemical Industry Co., Ltd.), 0.1 wt % of iodine (produced by Tokyo Chemical Industry Co., Ltd.), and 0.1 wt % of lithium iodide (produced by KISHIDA CHEMICAL Co., Ltd.) were added to produce an electrolyte. In the electrolyte, the weight ratio of the polymer 1 and BM-IMD is 7.5:2.5. With the use of this solution, was produced a cell in the same way as Example 1. Although the cell did not equip with any special sealing mechanism for preventing evaporation of solvent or liquid leakage, neither electrolytic liquid leakage nor evaporation of solvent arose in the obtained cell.

### Example 4

To a cell produced in the same way as Example 1 was irradiated with ultraviolet light at 3.8 J/cm² using 250 W high pressure mercury vapor lamp from the rear face of the counter electrode. Moreover, when the dimethylsulfoxide solution of the electrolyte composition of Example 1 was coated to the counter electrode and dried to obtain a dried electrolyte film, it was confirmed that flowability of the dried film was inhibited at high-temperature atmosphere (120° C.). In thus produced cell, although the cell did not equip with any special sealing mechanism for preventing evaporation of solvent or liquid leakage, neither electrolytic liquid leakage nor evaporation of solvent arose in the obtained cell.

### Comparative Example 1

The photoelectrode and the counter electrode were produced in the same way as Example 1, and these two electrodes were fixed with a clip. Subsequently, the electrolytic solution (produced by NISHINODA DENKO Co., Ltd.) was poured into the gap of two electrodes, and the cell of Comparative Example 1 was produced. As with the Example 1, the cell did not equip with any special sealing mechanism for preventing evaporation of solvent or liquid leakage. It was confirmed that the obtained cell causes electrolytic liquid leakage as well as evaporation of solvent. In particular in this case, the amount of the solvent between the gap of the substrates drastically reduced to make the substrate surface dried.

### Comparative Example 2

The photoelectrode and the counter electrode were produced in the same way as Example 1, and these two electrodes were fixed with a clip. Subsequently, the electrolytic solution prepared by dissolving 0.5 wt % of iodine (produced by Tokyo Chemical Industry Co., Ltd.) and 0.5 wt % of lithium iodide (produced by KISHIDA CHEMICAL Co., Ltd.) in BM-IMD (produced by Tokyo Chemical Industry Co., Ltd.) was poured into the gap of two electrodes, and the cell of Comparative Example 2 was produced. As with the Example 1, the cell did not equip with any special sealing mechanism for preventing evaporation of solvent or liquid leakage. It was confirmed that the obtained cell gives rise to electrolytic liquid leakage.

### Comparative Example 3

The photoelectrode and the counter electrode were produced in the same way as Example 1. The electrolytic solution was prepared with the use of dimethyl sulfoxide (produced by NACALAI TESQUE, INC.) as a solvent to dissolve 20 wt % of the polymer 1, 0.1 wt % of iodine (produced by Tokyo Chemical Industry Co., Ltd.) and 0.1 wt % of lithium iodide (produced by KISHIDA CHEMICAL Co., Ltd.). The weight ratio of the polymer 1 and BM-IMD is 10:0. By using the solution, a cell was produced in the same way as Example 1. Although the cell did not equip with any special sealing mechanism for preventing evaporation of solvent or liquid leakage, neither electrolytic liquid leakage nor evaporation of solvent arose in the obtained cell. The cell, however, had an extremely reduced photovoltaic power.

### Comparative Example 4

The photoelectrode and the counter electrode were produced in the same way as Example 1. The electrolytic solution was prepared with the use of dimethyl sulfoxide (produced by NACALAI TESQUE, INC.) as a solvent to dissolve 3 wt % of polymethacrylic acid [prepared by polymerizing methacrylic acid (produced by Tokyo Chemical Industry Co., Ltd.)], 17 wt % of BM-IMD (produced by Tokyo Chemical Industry Co., Ltd.), 0.1 wt % of iodine (produced by Tokyo Chemical Industry Co., Ltd.) and 0.1 wt % of lithium iodide (produced by KISHIDA CHEMICAL Co., Ltd.). The weight ratio of the polymethacrylic acid and BM-IMD is 1.5:8.5. By using the solution, a cell was produced in the same way as Example 1.

Further, as with Example 4, the produced cell was irradiated with ultraviolet light at 3.8 J/cm² using 250 W high pressure mercury vapor lamp from the rear face of the counter electrode. Although the cell did not equip with any special sealing mechanism for preventing evaporation of solvent or liquid leakage, neither electrolytic liquid leakage nor evaporation of solvent arose in the obtained cell. The cell, however, had an extremely reduced photovoltaic power.

The photovoltaic current and the electrical potential difference were measured for the cells produced in Examples and Comparative Examples. Measurement of the photovoltaic current and the electrical potential difference was performed directly under 12 W fluorescent light 2 times; first and second measurements were carried out 24 hours after cell production and one week after cell production, respectively. Moreover, observation of the cell to evaluate solvent evaporation and liquid leakage was performed at one week after cell production. The observation result is summarized in Table 1.

TABLE 1

| | Electrolytic formulation | | Photovoltaic current | | | | | | |
|---|---|---|---|---|---|---|---|---|---|
| | (Weight ratio) | | (Voltage value) | | | | Liquid | Solvent | |
| | Solidifying | | 24 hr after cell | | One week after | | leakage | evaporation | |
| | agent | Ionic liquid | production | | cell production | | [Evaluation] | [Evaluation] | Remark |
| Example 1 | Polymer 1 | BM-IMD | 313 | μA | 304 | μA | None | None | |
| | (1.5) | (8.5) | (0.43 | V) | (0.44 | V) | [Good] | [Good] | |
| Example 2 | Polymer 1 | BM-IMD | 540 | μA | 588 | μA | None | None | |
| | (1) | (9) | (0.38 | V) | (0.40 | V) | [Good] | [Good] | |
| Example 3 | Polymer 1 | BM-IMD | 74 | μA | 102 | μA | None | None | |
| | (7.5) | (2.5) | (0.40 | V) | (0.43 | V) | [Good] | [Good] | |
| Example 4 | Polymer 1 | BM-IMD | 477 | μA | 474 | μA | None | None | Irradiated by |
| | (1.5) | (8.5) | (0.40 | V) | (0.39 | V) | [Good] | [Good] | ultraviolet after cell |
| | | | | | | | | | production (3.8 J/cm2) |
| Comparative | None | Electrolytic | 340 | μA | 177 | μA | Occur | Occur | |
| Example 1 | (0) | solution | (0.39 | V) | (0.33 | V) | [Poor] | [Poor] | |
| | | (10) | | | | | | | |
| Comparative | None | BM-IMD | 238 | μA | 179 | μA | Occur | None | |
| Example 2 | (0) | (10) | (0.36 | V) | (0.36 | V) | [Poor] | [Good] | |
| Comparative | Polymer 1 | None | 0.1 | μA | 0.2 | μA | None | None | |
| Example 3 | (10) | (0) | (0.27 | V) | (0.28 | V) | [Good] | [Good] | |
| Comparative | Polymethacrylic acid | BM-IMD | 289 | μA | 293 | μA | None | None | Irradiated by |
| Example 4 | (1.5) | (8.5) | (0.37 | V) | (0.36 | V) | [Good] | [Good] | ultraviolet after cell |
| | | | | | | | | | production (3.8 J/cm2) |

In Examples 1 to 4, as shown in Table 1, even if iodine was included, the crosslinking could be proceeded and the liquid leakage from the cells and evaporation of solvent were not occurred. Moreover, the photovoltaic current hardly reduced not only immediately after cell production but also one week after cell production. Further, the photovoltaic current increased in Examples 2 and 3 at one week after cell production.

On the other hand, in Comparative Examples 1 and 2 without the photocrosslinkable liquid crystal polymer, liquid leakage from the cells and evaporation of solvent were occurred to show poor durability. Moreover, in Comparative Example 3 without the ionic liquid, electromotive force was hardly confirmed.

Furthermore, in Example 4 in which ultraviolet was irradiated to the cell of Example 1, it has been confirmed that a photovoltaic current increased as compared with Example 1.

FIG. 2 shows relationship between an amount of ultraviolet irradiation and photovoltaic-current value. The ultraviolet light was irradiated to the cell of Example 4 as well as to the cell of Comparative Example 4 from the rear surface of the counter electrode. The cell of Example 4 was formed by using the electrolyte composition of the present invention, whereas the cell of Comparative Example 4 was formed by using the electrolyte containing the polymer having a carboxyl group but never showing photo reactivity nor liquid crystallinity. FIG. 2 reveals that photovoltaic current is greatly enhanced in the cell using the electrolyte composition of Example 4 compared with that of Comparative Example 4. Further, as the amount of ultraviolet irradiation increased, the generated photovoltaic current increased.

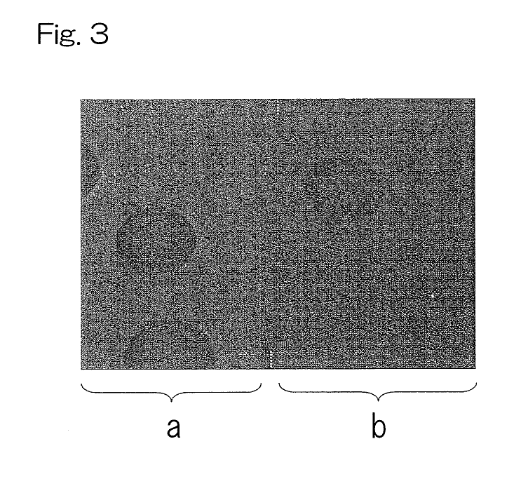

Moreover, FIG. 3 shows a view showing an image of the ultraviolet-irradiated electrolyte composition of one embodiment of the present invention obtained by observation using a polarization microscope under crossed-Nicol. In FIG. 3, Area “a” is an ultraviolet-irradiated part; Area “b” is an ultraviolet-non-irradiated part.

FIG. 3 shows that the light penetration is enhanced only in the area where ultraviolet was irradiated. It is thought that such a light penetration is caused by liquid crystallinity and photo reactivity of the polymer having the functional group shown as the chemical formula (2). Occurrence of such light penetration suggests that small domains are formed in the electrolyte to arise the phase-separated structure.

Example 4 in which ultraviolet was irradiated had generated the photovoltaic current higher than Example 1. It is considered that such improved cell performance may be caused by phase-separated structure produced by light irradiation as with the case of Reference 1 in which solar cell characteristics are improved by the phase-separated structure.

On the other hand, although not illustrated, in the electrolyte comprising the polymer of Comparative Example 4, the polymer which does not show optical reactivity nor liquid crystallinity but has carboxyl group, such a phase-separated structure did not arise by ultraviolet irradiation, and cell characteristics were not improved sharply.

### INDUSTRIAL APPLICABILITY

According to the present invention, while being able to obtain an electrolyte being gelled or solidified in a simple way, the dye-sensitized solar cell using this electrolyte can be obtained.

As mentioned above, the preferred embodiments of the present invention are illustrated, but it is to be understood that other embodiments may be included, and that various additions, other changes or deletions may be made, without departing from the spirit or scope of the present invention.

What is claimed is:

1. A photocrosslinkable electrolyte composition comprising a redox pair, an ionic liquid, and a photocrosslinkable liquid crystal polymer having a functional group represented by the following chemical formula (1): 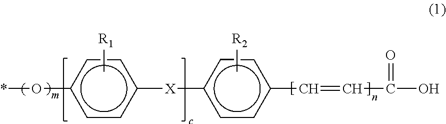
wherein, m is 0 or 1; n is 1 to 3; c is 0 or 1; X is none, O, CH₂, N═N, C═C, C≡C, COO, or OCO; R₁ and R₂ are each representing H, an alkyl group, an alkyloxy group, or a halogen.

2. The electrolyte composition as claimed in claim 1, wherein the redox pair is a redox pair of iodine.

3. The electrolyte composition as claimed in claim 1, wherein the ionic liquid is at least one member selected from the group consisting of a nitrogen-containing heterocyclic compound, an alicyclic amine, a fatty amine, and an aromatic amine.

4. The electrolyte composition as claimed in claim 1, wherein the photocrosslinkable liquid crystal polymer and the ionic liquid have a weight ratio (former/latter) of from 7/93 to 90/10.

5. A photocrosslinked electrolyte formed by light irradiation to the electrolyte composition recited in claim 1.

6. A photocrosslinked electrolyte as claimed in claim 5, wherein the irradiated light is an ultraviolet of the wavelength of 380 nm or less.

7. A dye-sensitized solar cell comprising:
a photoelectrode having an acceptance surface on one side,
a counter electrode arranged on the opposing side of the acceptance surface of the photoelectrode, and
the photocrosslinked electrolyte recited in claim 5 sandwiched between these two sheets of electrodes.
